(19) United States
(12) Patent Application Publication
(10) Pub. No.: US 2023/0127340 A1
(43) Pub. Date: Apr. 27, 2023

(54) FAN MODES BASED ON TEMPERATURE THRESHOLDS

(71) Applicant: Hewlett-Packard Development Company, L.P., Spring, TX (US)

(72) Inventors: Chien-Hao Lu, Taipei City (TW); Chia Ching Lu, Taipei City (TW); Chien Wei Ho, Taipei City (TW)

(21) Appl. No.: 17/509,385

(22) Filed: Oct. 25, 2021

(51) Int. Cl. H05K 7/20; G05B 15/02; G06F 1/20

(52) U.S. Cl. CPC H05K 7/20209; H05K 7/20172; G05B 15/02; G06F 1/206

(57) ABSTRACT

In some examples, the disclosure describes a device that includes heat generating devices, a fan, and a processor to: determine a temperature within an area of the heat generating devices, activate the fan in a pulse width modulation (PWM) mode in response to the temperature being above a temperature threshold, activate the fan in a direct current (DC) mode in response to the temperature being below the temperature threshold.

### BACKGROUND

Computing devices are utilized to perform particular functions. The computing devices utilize hardware computing components that generate heat within an enclosure of the computing device. Components of a computing device may operate within a particular temperature range. Fans are utilized to prevent a temperature of components exceeding an upper threshold temperature within the enclosure.

### BRIEF DESCRIPTION OF THE DRAWINGS

FIG. 1 illustrates an example of a device for adjusting fan modes based on temperature thresholds.

FIG. 2 illustrates an example of a memory resource for adjusting fan modes based on temperature thresholds.

FIG. 3 illustrates an example of a system for adjusting fan modes based on temperature thresholds.

FIG. 4 illustrates an example of a flow diagram for adjusting fan modes based on temperature thresholds.

### DETAILED DESCRIPTION

A user may utilize a computing device for various purposes, such as for business and/or recreational use, As used herein, the term computing device refers to an electronic device having a processor and a memory resource. Examples of computing devices can include, for instance, a laptop computer, a notebook computer, a desktop computer, an all-in-one (AIO) computer, and/or a mobile device (e.g., a smart phone, tablet, personal digital assistant, smart glasses, a wrist-worn device, etc.), among other types of computing devices. Computing devices can be utilized to perform a plurality of computing functions. Computing devices utilize a plurality of components (e.g., hardware computing components, etc.) to perform the functions. In some examples, the plurality of components generate heat when performing the plurality of functions.

Cooling systems are utilized to lower a temperature and/or maintain a temperature. Some cooling systems include a fan or a plurality of fans to move warm air away from the plurality of components or heat generating devices. In some examples, the fan or plurality of fans consume electrical power during operation. There can be power limitations for the fan or plurality of fans. For example, the computing device can receive a limited quantity of power or prefer to utilize a relatively low quantity of power to conserve electrical power usage or battery power. In some examples, the fan or plurality of fans include a direct current (DC) fan, alternate current (AC) fan, or a pulse width modulation (PWM) fan.

A DC fan can be supplied with DC power from regulated DC power supply or motherboard header pins. DC fans are also referred to as 3-pin fans since a DC fan includes three pins. In these examples, the three pins include a supply pin (e.g., pin to receive DC voltage, a pin to receive 12 volts (V) DC), a ground pin, and a signal pin. In some examples, the PWM fan includes a DC fan or three pin fan with an extra wire for receiving a PWM signal. PWM fans are also referred to as a four pin fans. In these examples, the first pin is a supply pin, the second pin is a ground pin, the third pin is a signal pin and the fourth pin is a PWM signal pin to receive a PWM signal. In some examples, the PWM signal is the control input of the PWM fan. In some examples, the control input is an open-drain or open-collector output with a particular voltage (e.g., 5 V, 3.3 V pull-up, etc.). The PWM control signals are square waves of high frequency, usually 25 kilohertz (kHz) or above, to make the noise from the fan above the audible human hearing range. The PWM signal can start or stop the motor of the fan, depending on the high and low state of the PWM signal. When the PWM signal is high, the motor is activated or rotating to spin the fan. When the PWM signal is low, the motor is deactivated or not rotating the fan.

A DC fan includes some advantages over a PWM fan and a PWM fan includes some advantages over a DC fan. To ensure that a mode of the fan for a computing device is operating at a relatively high performance and utilizing a relatively low electrical consumption, a hybrid fan can be utilized that allows a fan to operate in a DC mode to emulate a DC fan and a PWM mode to emulate a PWM fan. The present disclosure relates to adjusting fan modes based on temperature thresholds. In this way, a processor can adjust a single fan between the DC mode and the PWM mode based on a temperature threshold within the enclosure of the computing device and/or based on a selection of a power saving mode. As used herein, a power saving mode includes a mode of operation for a computing device that lowers a power consumption of components within the computing device below a threshold level to conserve the usage of electrical power by the computing device.

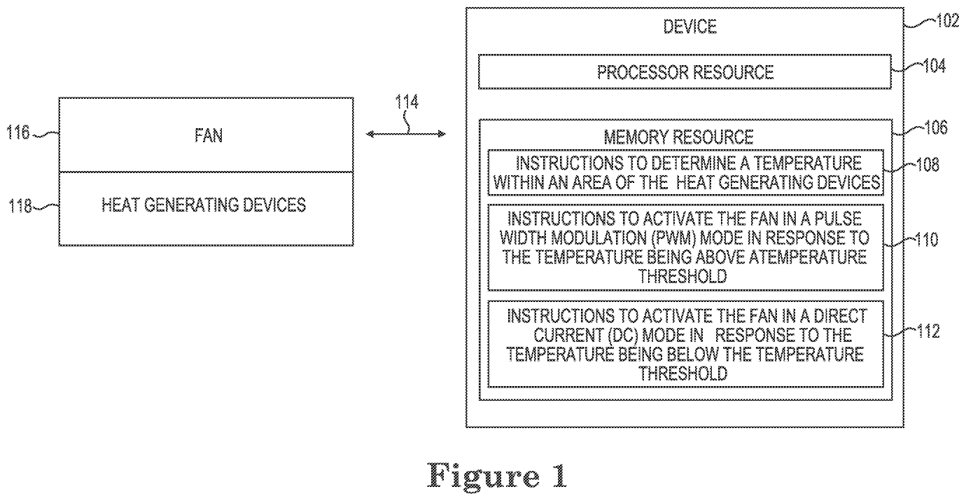

FIG. 1 illustrates an example of a device 102 for adjusting fan modes based on temperature thresholds. In some examples, the device 102 includes a processor resource 104 and a memory resource 106 to store instructions that are executed by the processor resource 104. In some examples, the device 102 includes a computing device that includes a processor resource 104 and a memory resource 106 storing instructions 108, 110, 112, that can be executed by the processor resource 104 to perform particular functions.

The device 102 includes instructions 108 stored by the memory resource 106 that is executed by the processor resource 104 to determine a temperature within an area of the heat generating devices 118. In some examples, the device 102 can be coupled to a temperature sensor that can provide a signal to the device 102 to allow the device 102 to determine the temperature within an area surrounding the heat generating devices 118. For example, the heat sensor can be positioned relatively close or proximate to the heat generating devices 118 to determine a temperature that can be utilized to determine an operating temperature of the heat generating devices 118. In some examples, a distance between the heat generating devices 118 and temperature sensor can be utilized to determine an operating temperature or temperature at the heat generating devices. For example, the sensed temperature at the temperature sensor and the distance can be utilized to calculate the operating temperature of the heat generating devices.

In some examples, the heat generating devices 118 are components of a computing device and/or components of the device 102. In some examples, the heat generating components 118 are processors, electrical connections, transistors, capacitors, resistors, and/or other electrical components that can generate heat within an enclosure of a device 102. In some examples, the heat generating devices 118 generate different quantities of heat based on a level of performance or activity. For example, a processor such as processor resource 104 may generate a first quantity of heat when operating at a relatively low level and generate a second quantity of heat when operating at a relatively high level In this example, the second quantity of heat is larger than the first quantity of heat.

In some examples, the quantity of heat generated by the heat generating devices 118 is based in part on a quantity of electrical power utilized by the heat generating devices 118. For example, the heat generating devices utilize a relatively higher quantity of electrical energy when performing a higher quantity of functions or performing more complex functions. In this example, the heat generating devices 118 generate heat based on a performance level of the heat generating devices 118. In some examples, the device 102 utilizes a plurality of modes associated with the performance of the heat generating devices 118. In some examples, a normal mode corresponds to a first level of performance for the device 102, a turbo mode corresponds to a second level of performance for the device 102 that is greater than the normal mode, and a power saver mode corresponds to a third level of performance for the device 102 that is less than the normal mode. In this way, the heat generating devices 118 may generate more heat in the turbo mode than the normal mode and less heat in the power saver mode than the normal mode.

The device 102 can include instructions 110 stored by the memory resource 106 that can be executed by the processor resource 104 to activate the fan 116 in a pulse width modulation (PWM) mode in response to the temperature being above a temperature threshold. In some examples, the determined temperature is a relative temperature associated with the heat generating devices 118. As described herein, the heat generating devices 118 may be negatively affected when the temperature of the heat generating devices exceeds a particular temperature. In some examples, the temperature threshold is based on the particular temperature that could negatively affect the functionality or performance of the heat generating devices. Thus, the PWM mode for the fan 116 is activated when the temperature of the heat generating devices 118 or area surrounding the heat generating devices 118 reaches a temperature that is relatively close to a temperature that could damage the heat generating devices 118.

In some examples, the fan 116 is a hybrid fan that can operate in a PWM mode and a DC mode separately. That is, in the PWM mode the fan 116 is receiving a PWM signal to control an input control of the fan 116. In some examples, the PWM mode of the fan 116 allows a speed of the fan 116 to be controlled by the PWM signal. In some examples, the speed of the fan 116 is able to be adjusted to a plurality of different speeds while the speed of the fan 116 is limited to fewer speeds when the fan 116 is in the DC mode. When the fan 116 is switched from the PWM mode to the DC mode, the PWM signal is stopped or prevented from controlling the input control of the fan 116. In the DC mode, the PWM signal does not affect the input control of the fan 116. In the DC mode, a DC voltage is applied to the fan 116 and the DC input for the fan 116 is adjustable to alter a speed of the fan 116 while in the DC mode. In some examples, the fan 116 includes a voltage at common collector (VCC) power range of 4 volts to 16 volts to allow the fan 116 to be utilized in either the PWM mode or the DC mode.

In some examples, the device 102 includes instructions to provide a hybrid DC mode and PWM mode to reduce power consumption. In the hybrid DC mode and PWM mode includes maintaining the PWM signal at a relatively low frequency. For example, the frequency of the PWM signal is altered to a level below a threshold frequency. In this example, the PWM signal can have a ten percent or lower duty cycle. That is, the threshold PWM signal duty cycle or frequency is ten percent. In these examples, the DC voltage is reduced while the PWM signal is able to increase or decrease the speed of the fan 116.

In a specific example, DC mode can utilize 0.12 Watts (W) when the voltage provided to the fan 116 is 12 volts (V) and the fan 116 can have a speed of 651 rotations per minute (rpm) when the PWM signal duty cycle is 10%. In this example, the DC voltage can be altered from 12 V to 5 V to have the fan 116 utilize 0.05 W while having a speed of 282 rpm. In this example, the PWM signal can be increased from 10% to 60% to provide the speed of 282 rpm with a relatively lower power consumption of 0.10 W. In this way, the hybrid DC mode and PWM mode can provide a relatively high fan speed for the fan 116 while decreasing the power consumption of the fan 116.

The device 102 can include instructions 112 stored by the memory resource 106 that can be executed by the processor resource 104 to activate the fan 116 in a direct current (DC) mode in response to the temperature being below the temperature threshold. As described herein, the fan 116 can switch between the PWM mode and the DC mode in response to a determined temperature associated with the heat generating devices 118. In some examples, the PWM mode is deactivated, and the DC mode is activated. In this way, the PWM signal is no longer provided to the fan 116 during the DC mode. That is, the PWM mode and the DC mode operate independently.

In some examples, the processor resource 104 activates the fan 116 in the DC mode in response to the device 102 being in a power saving mode. In some examples, the power saving mode restricts a quantity of electrical power from being provided or utilized by the heat generating devices 118. In this way, the power saving mode utilizes less power or electrical energy while in the power saving mode. In some examples, the DC mode is activated to reduce power consumption of the fan 116 while the device 102 is in the power saving mode.

In some examples, the processor resource 104 sends a signal to a voltage regulator to activate the fan 116. In some examples, a voltage regulator or power supply is utilized to provide electrical energy to components of the device 102 such as the fan 116. In some examples, the voltage regulator can provide consistent voltage and/or amperage to a component such as the fan 116. In some examples, the voltage regulator can alter the power or quantity of volts that are output by the voltage regulator and provided to the fan 116 at a particular time.

In some examples, the processor resource 104 deactivates a particular power regulator in response to the fan 116 being activated in the DC mode. In some examples, the particular power regulator includes a particular electrical connection being disconnected from being powered. For example, the PWM signal that is provided to the fan 116 in the PWM mode can be generated by a controller or processor that is coupled to the particular power regulator. In this example, the particular electrical connection or particular power regulator is deactivated since the PWM signal is not needed during the DC mode. In these examples, deactivating the particular power regulator saves additional electrical energy that would have been utilized by the controller or processor generating the PWM signal. In one example, the particular power regulator is a 12-volt power regulator to allow a different power regulator to provide power to the fan during the DC mode. In this example, the 12-volt power regulator is connected to a controller generating the PWM signal and the different power regulator is a different 12 volt power regulator that is connected to the fan 116.

In some examples, the processor resource 104 utilizes a step increase and step decrease during the DC mode based on fan acoustics. In these examples, an acoustic sensor is utilized to determine fan acoustics for the fan 116. In some examples, the step increases and/or step decrease is a particular quantity of voltage increase and/or decrease. In this way, the voltage is altered by the power regulator is performed in step increases or step decreases. When a step increase or step decrease is to be performed the fan acoustics can be utilized to determine a time for the voltage regulator to execute the step increase or step decrease.

As described herein, the device 102 can include a computing device that can include a processor resource 104 communicatively coupled to a memory resource 106. As used herein, the processor resource 104 can include, but is not limited to: a central processing unit (CPU), an application specific integrated circuit (ASIC), a field programmable gate array (FPGA), a metal-programmable cell array (MPCA), a semiconductor-based microprocessor, or other combination of circuitry and/or logic to orchestrate execution of instructions 108, 110, 112. In other examples, the computing device can include instructions 108, 110, 112, stored on a machine-readable medium (e.g., memory resource 106, non-transitory computer-readable medium, etc.) and executable by a processor resource 104. In a specific example, the computing device utilizes a non-transitory computer-readable medium storing instructions 108, 110, 112, that, when executed, cause the processor resource 104 to perform corresponding functions.

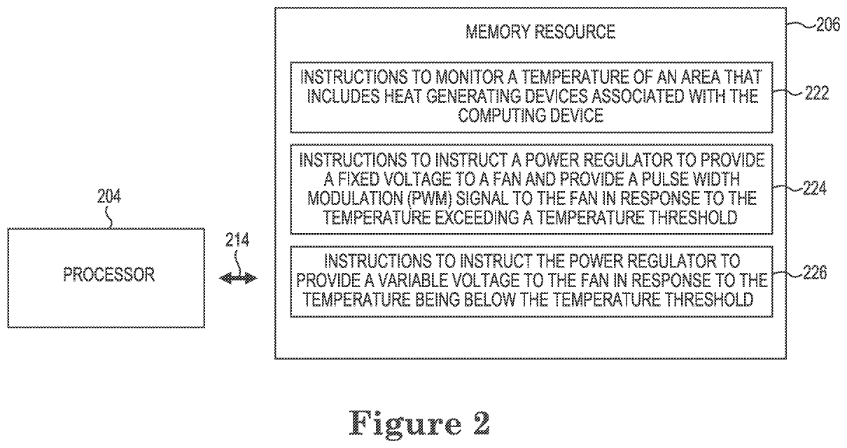

FIG. 2 illustrates an example of a memory resource 206 for adjusting fan modes based on temperature thresholds. In some examples, the memory resource 206 can be a part of a computing device or controller that can be communicatively coupled to a computing system. For example, the memory resource 206 can be part of a device 102 as referenced in FIG. 1. In some examples, the memory resource 206 can be communicatively coupled to a processor 204 that can execute instructions 222, 224, 226, stored on the memory resource 206. For example, the memory resource 206 can be communicatively coupled to the processor 204 through a communication path 214. In some examples, a communication path 214 can include a wired or wireless connection that can allow communication between devices and/or components within a single device.

The memory resource 206 may be electronic, magnetic, optical, or other physical storage device that stores executable instructions. Thus, a non-transitory machine-readable medium (MRM) (e.g., a memory resource 206) may be, for example, a non-transitory MRM comprising Random-Access Memory (RAM), read-only memory (ROM), an Electrically-Erasable Programmable ROM (EEPROM), a storage drive, an optical disc, and the like. The non-transitory machine-readable medium (e.g., a memory resource 206) may be disposed within a controller and/or computing device. In this example, the executable instructions 222, 224, 226, can be “installed” on the device. Additionally, and/or alternatively, the non-transitory machine-readable medium (e.g., a memory resource) can be a portable, external, or remote storage medium, for example, that allows a computing system to download the instructions 222, 224, 226, from the portable/external/remote storage medium. In this situation, the executable instructions may be part of an “installation package”. As described herein, the non-transitory machine-readable medium (e.g., a memory resource 206) can be encoded with executable instructions for altering a dynamic power reduction mode of a radio.

In some examples, the memory resource 206 can include instructions 222 to monitor a temperature of an area that includes heat generating devices associated with the computing device. As described herein, heat generating devices include electrical devices utilized by a computing device or other type of electrical device to perform particular functions. In some examples, the area that includes the heat generating devices includes an area within an enclosure of the computing device. In this way, the internal temperature of the enclosure of the computing device is monitored to ensure that a temperature of the heat generating devices does not damage the heat generating devices or negatively alter performance of the heat generating devices.

In some examples, the memory resource 206 can include instructions 224 to instruct a power regulator to provide a fixed voltage to a fan and provide a pulse width modulation (PWM) signal to the fan in response to the temperature exceeding a temperature threshold. In some examples, a temperature sensor can provide a signal to the memory resource 206 that can be utilized to calculate a temperature or operating temperature of the area that includes the heat generating devices. In some examples, the power regulator is a voltage regulator that provides electrical power to the fan. In some examples, the power regulator provides a fixed voltage to the fan and provides voltage to a controller (e.g., embedded controller, etc.) to enable the controller to provide the PWM signal to the fan. As described herein, the fan is in a PWM mode when a PWM signal is provided to the fan to control a speed of the fan during operation.

In some examples, the memory resource 206 can include instructions 226 to instruct the power regulator to provide a variable voltage to the fan in response to the temperature being below the temperature threshold. In some examples, the memory resource includes instructions to deactivate the PWM signal and/or deactivate the controller that provides the PWM signal and switch the fan from the PWM mode to a direct current (DC) mode. As described herein, the DC mode includes a mode of the fan where the power regulator controls a speed of the fan based on a voltage provided to the fan. For example, a variable voltage includes a first voltage being provided to the fan during a first time period and a second voltage being provided to the fan during a second time period. In this example, the power regulator can perform a step down or step up operation to change the voltage provided to the fan.

In some examples, the memory resource 206 includes instructions to instruct the power regulator to provide a step variable voltage to the fan in response to the temperature being below the temperature threshold and a power saving mode being activated. As described herein, the PWM mode is deactivated, and a DC mode is activated to conserve power of a computing device while still providing cooling to the heat generating components. In some examples, the step variable voltage provided to the fan can include stepping up from the first voltage to the second voltage and/or stepping down from the second voltage to the second first voltage. In some examples, a step up or step down can include altering from the full first voltage to the full second voltage without applying a voltage between the first voltage and the second voltage.

In some examples, the memory resource 206 includes instructions to deactivate the PWM signal to the fan in response to the power regulator being instructed to provide the variable voltage to the fan. As described herein, the PWM signal can be deactivated by instructing a controller that is generating the PWM signal to discontinue generating the PWM signal. In other examples, the PWM is deactivated by deactivating the controller that is generating the PWM signal. In some examples, a connection between the controller generating the PWM signal and the fan is disconnected such that the fan is no longer receiving the PWM signal.

In some examples, the memory resource 206 includes instructions to determine acoustics associated with the fan and provide the variable voltage to the fan based on the determined acoustics. As described herein, acoustics can be generated by the fan during operation. In some examples, the acoustics or sound generated by the fan are distracting to a user. In some examples, a timing of the variable voltage and/or voltage transition can be based on the acoustics of the fan to prevent the acoustics from being distracting to a user or be within a particular sound range.

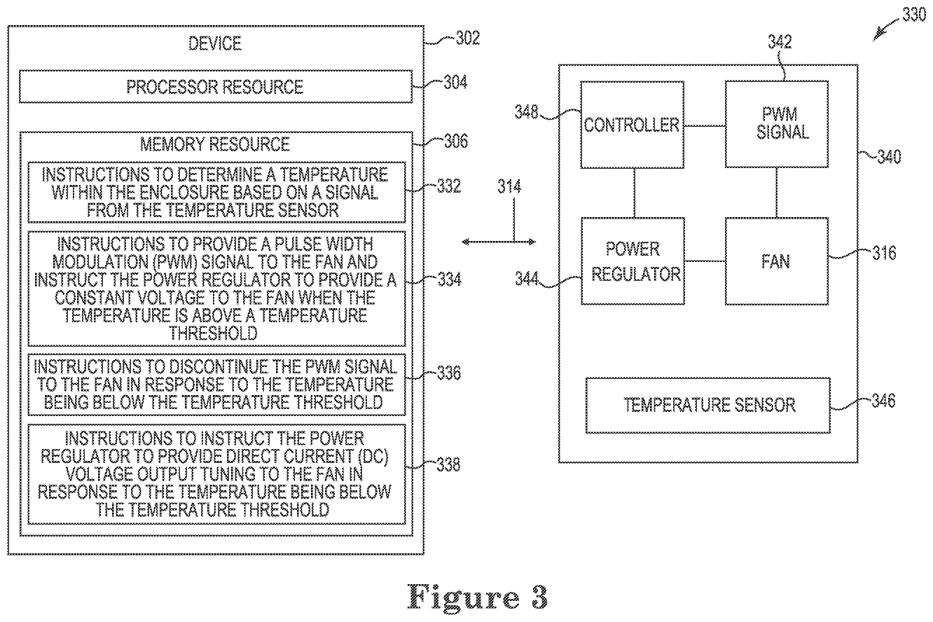

FIG. 3 illustrates an example of a system 330 for adjusting fan modes based on temperature thresholds. In some examples, the system 330 includes a device 302 that includes a processor 304 communicatively coupled to a memory resource 306. In some examples, the device 302 can include a computing device that includes a processor 304 and a memory resource 306 storing instructions 332, 334, 336, 338, that are executed by the processor 304 to perform particular functions.

The system 300 includes an enclosure 340 that includes a plurality of components. In some examples, the device 302 is positioned within the enclosure 340 or is part of a computing device. In some examples, the device 302 is communicatively coupled to the components within the enclosure 340 through a communication path 314. In some examples, the enclosure 340 includes a power regulator 344 to provide electrical power to components within the enclosure 340 and/or components coupled to ports of the enclosure 340. In some examples, the power regulator 344 provides direct current (DC) power to the fan 316 and/or a controller 348.

As described herein, during a PWM mode the power regulator 344 provides power to the controller 348 to generate a PWM signal 342 that is provided to the fan 316. In contrast, during a DC mode, the power regulator 344 may not provide power to the controller 348 and provide power to the fan 316 utilizing variable voltage steps. In this way, the power regulator 344 can switch the mode of the fan 316 from a PWM mode to a DC mode and/or from a DC mode to a PWM mode. In some examples, the power regulator receives instructions from the device 302 that indicate when the fan 316 is to be operating in the DC mode or the PWM mode. In some examples, the device 302 receives data from a temperature sensor 346 related to a current temperature within the enclosure 340 and/or an operating temperature of the components within the enclosure 340. As described herein, the device 302 receives the temperature data from the temperature sensor 346 through the communication path 314 and determines a mode of the fan 316 based on the temperature and/or whether the system 330 is in a power saving mode.

The device 302 includes instructions 332 stored by the memory resource 306 that can be executed by the processor 304 to determine a temperature within the enclosure 340 based on a signal from the temperature sensor 346. As described herein, the temperature sensor 346 detects a temperature within the enclosure 340 and provides temperature data to the device 302. In some examples, the temperature sensor 346 is proximate to heat generating components within the enclosure 340. In some examples, the temperature sensor 346 is positioned within the disclosure at a location with a known distance between the temperature sensor 346 and heat generating components. In these examples, the temperature data and distances are utilized to calculate a temperature for the components within the enclosure 340.

The device 302 includes instructions 334 stored by the memory resource 306 that can be executed by the processor 304 to provide a pulse width modulation (PWM) signal 342 to the fan 316 and instruct the power regulator 344 to provide a constant voltage to the fan 316 when the temperature is above a temperature threshold. As described herein, the temperature calculated based on the temperature data from the temperature sensor 346 is utilized to determine a mode of the fan 316. The fan 316 is put into a PWM mode when the temperature within the enclosure 340 is above the threshold temperature and/or when the system is not in a power saving mode. As described herein, a controller 348 or device 302 generates the PWM signal 342 that is provided to the fan 316 during the PWM mode. In some examples, the power regulator 344 activates the controller 348 to generate the PWM signal 342 to be provided to the fan 316.

The device 302 includes instructions 336 stored by the memory resource 306 that can be executed by the processor 304 to discontinue the PWM signal 342 to the fan 316 in response to the temperature being below the temperature threshold. In some examples, the PWM signal 342 is discontinued by deactivating the controller 348 that generates the PWM signal 342 by restricting electrical power provided by the power regulator 344. In this way, the system 330 can lower electrical power consumption when the temperature changes and falls below the temperature threshold. In addition, the fan 316 is still activated to prevent a relatively quick rise in temperature since the fan 316 can be altered from the PWM mode to the DC mode.

The device 302 includes instructions 338 stored by the memory resource 306 that can be executed by the processor 304 to instruct the power regulator 344 to provide direct current (DC) voltage output tuning to the fan 316 in response to the temperature being below the temperature threshold. As described herein, the DC mode of the fan 316 is activated when the PWM mode is deactivated in response to the temperature falling below the temperature threshold. In some examples, the device 302 includes instructions to instruct the power regulator 344 to provide a step increase or a step decrease DC voltage to the fan 316 based on the acoustic values of the fan. In these examples, the DC voltage output tuning includes performing step up or step down voltage changes to the fan 316 by the power regulator 344 to alter a speed of the fan 316 based on the provided DC voltage from the power regulator 344.

In some examples, the device 302 includes instructions to discontinue the DC voltage output tuning to the fan in response to the temperature being above the temperature threshold and provide the PWM signal 342 to the fan 316 while the power regulator 344 is instructed to provide the constant voltage to the fan 316. In some examples, the DC mode is deactivated or discontinued when the temperature within the enclosure 340 rises above the temperature threshold. In some examples, the PWM mode is activated in response to the DC mode being deactivated. As described herein, the PWM signal 342 is utilized to alter a speed of the fan 316 while the voltage regulator 344 provides a constant or substantially constant DC voltage to the fan 316.

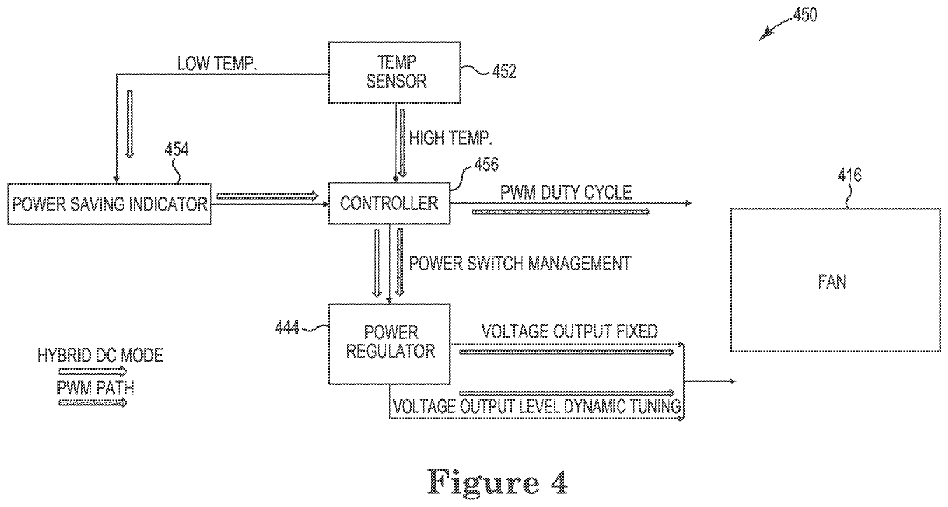

FIG. 4 illustrates an example of a flow diagram 450 for adjusting fan modes based on temperature thresholds. In some examples, the flow diagram 450 includes components of a device (e.g., device 102 as referenced in FIG. 1) or system (e.g., system 330 as reference in FIG. 3) as well as a method that can be executed by a device or system.

In some examples, the flow diagram 450 starts by determining a temperature of a device or components of a device utilizing a temperature sensor 452. As used herein, a temperature sensor 452 includes a device that can determine a temperature reading and provide temperature data to a controller 456. In some examples, the temperature sensor 452 can determine that a temperature is a “low temperature” or below a temperature threshold or that the temperature is a “high temperature” or above the temperature threshold.

The flow diagram 450 can move to determining if the device or system is in a power saving mode based on a power saving indicator 454 when the temperature sensor 452 indicates that the device or system is at a “low temperature”. As described herein, the power saving mode can restrict power usage for components of the device or system. In some examples, the indication of the power saving indicator 454 that the device or system is in a power saving mode can restrict or limit the maximum power utilized by the components of the device or system. In this way, the device or system can lower an overall power consumption.

The flow diagram 450 can include a controller 456 that can receive temperature data and power saving indications from the temperature sensor 452 and the temperature sensor 452 respectively. In some examples, the controller 456 is a computing device that can include a processor and memory resource storing instructions to perform functions. In some examples, the controller 456 can provide signals to the power regulator 444 to activate or deactivate the PWM mode and DC mode of the fan 416. In some examples, the controller 456 provides a PWM duty signal to the fan 416 during a PWM mode to control a speed of the fan 416 through the PWM signal. During the PWM mode of the fan 416, the power regulator 444 provides a fixed voltage to the fan 416 when the temperature is above a threshold temperature while the controller 456 provides the PWM duty cycle signal to the fan 416.

The power regulator 444 deactivates the PWM signal to the fan and provides voltage output level dynamic tuning to the fan when the temperature is below the threshold temperature. As described herein, the output level dynamic tuning or step level tuning includes a voltage step up or step down to dynamically tune the speed of the fan 416 based on the voltage provided to the fan 416. In these examples, the electrical power utilized to power the fan 416 is decreased and helps with a power saving mode of the device or system. For example, the controller 456 can be deactivated or prevented from generating the PWM duty cycle for the fan 416, which can lower the electrical power utilized by the controller 456 and/or power provided by the power regulator 444.

In the foregoing detailed description of the disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the disclosure. Further, as used herein, “a” refers to one such thing or more than one such thing.

The figures herein follow a numbering convention in which the first digit corresponds to the drawing figure number and the remaining digits identify an element or component in the drawing. For example, reference numeral 102 may refer to element 102 in FIG. 1 and an analogous element may be identified by reference numeral 302 in FIG. 3. Elements shown in the various figures herein can be added, exchanged, and/or eliminated to provide additional examples of the disclosure. In addition, the proportion and the relative scale of the elements provided in the figures are intended to illustrate the examples of the disclosure, and should not be taken in a limiting sense.

It can be understood that when an element is referred to as being “on,” “connected to”, “coupled to”, or “coupled with” another element, it can be directly on, connected, or coupled with the other element or intervening elements may be present. In contrast, when an object is “directly coupled to” or “directly coupled with” another element it is understood that are no intervening elements (adhesives, screws, other elements) etc.

The above specification, examples, and data provide a description of the system and methods of the disclosure. Since many examples can be made without departing from the spirit and scope of the system and method of the disclosure, this specification merely sets forth some of the many possible example configurations and implementations.

What is claimed is:

1. A device, comprising:
a heat generating device;
a fan; and
a processor to:
determine a temperature within an area of the heat generating device;
activate the fan in a pulse width modulation (PWM) mode in response to the temperature being above a temperature threshold;
activate the fan in a direct current (DC) mode in response to the temperature being below the temperature threshold.

2. The device of claim 1, wherein the processor is to activate the fan in the DC mode in response to the device being in a power saving mode.

3. The device of claim 1, wherein the processor is to send a signal to a voltage regulator to activate the fan.

4. The device of claim 1, wherein the fan includes a voltage at common collector (VCC) power range of 4 volts to 16 volts.

5. The device of claim 1, wherein the processor is to deactivate a particular power regulator in response to the fan being activated in the DC mode.

6. The device of claim 5, wherein the particular power regulator is a 12 volt power regulator to allow a different power regulator to provide power to the fan during the DC mode.

7. The device of claim 1, wherein the processor is to utilize a step increase and step decrease during the DC mode based on fan acoustics.

8. A non-transitory memory resource storing machine-readable instructions stored thereon that, when executed, cause a processor of a computing device to:
monitor a temperature of an area that includes heat generating devices associated with the computing device;
instruct a power regulator to provide a fixed voltage to a fan and provide a pulse width modulation (PWM) signal to the fan in response to the temperature exceeding a temperature threshold; and
instruct the power regulator to provide a variable voltage to the fan in response to the temperature being below the temperature threshold.

9. The memory resource of claim 8, wherein the processor is to instruct the power regulator to provide a step variable voltage to the fan in response to the temperature being below the temperature threshold and a power saving mode being activated.

10. The memory resource of claim 8, wherein the processor is to deactivate the PWM signal to the fan in response to the power regulator being instructed to provide the variable voltage to the fan.

11. The memory resource of claim 8, wherein the processor is to determine acoustics associated with the fan and provide the variable voltage to the fan based on the determined acoustics.

12. A system, comprising:
an enclosure including a plurality of hardware computing components;
a temperature sensor;
a fan within the enclosure;
a power regulator to provide a voltage to the fan; and
a processor to:
determine a temperature within the enclosure based on a signal from the temperature sensor;
provide a pulse width modulation (PWM) signal to the fan and instruct the power regulator to provide a constant voltage to the fan when the temperature is above a temperature threshold; and
discontinue the PWM signal to the fan in response to the temperature being below the temperature threshold;
instruct the power regulator to provide direct current (DC) voltage output tuning to the fan in response to the temperature being below the temperature threshold.

13. The system of claim 12, wherein the processor is to discontinue the DC voltage output tuning to the fan in response to the temperature being above the temperature threshold and provide the PWM signal to the fan while the power regulator is instructed to provide the constant voltage to the fan.

14. The system of claim 12, comprising an acoustic sensor to determine acoustic values of the fan.

15. The system of claim 14, wherein the processor is to instruct the power regulator to provide a step increase or a step decrease DC voltage to the fan based on the acoustic values of the fan.
